(19) United States
(12) Patent Application Publication
(10) Pub. No.: US 2006/0216647 A1
(43) Pub. Date: Sep. 28, 2006

(54) Photopolymerizable composition, light sensitive planographic printing plate material and manufacturing method of planographic printing plate

(75) Inventor: Keiko Ishidai, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: KONICA MINOLTA MEDICAL & GRAPHIC, INC., Tokyo (JP)

(21) Appl. No.: 11/371,397

(22) Filed: Mar. 9, 2006

(30) Foreign Application Priority Data
Mar. 23, 2005 (JP) JP2005-083354

(51) Int. Cl. G03F 7/00

(52) U.S. Cl. 430/302

(57) ABSTRACT

Disclosed is a photopolymerizable composition containing an ethylenically unsaturated monomer, a photopolymerization initiator and a sensitizing dye, wherein the photopolymerization initiator is comprised of an iron-arene compound and a tribromoacetic acid ester having a molecular weight of not less than 500, and the sensitizing dye is at least one selected from the group consisting of compounds represented by the following formulae (A1), (A2) and (A3),

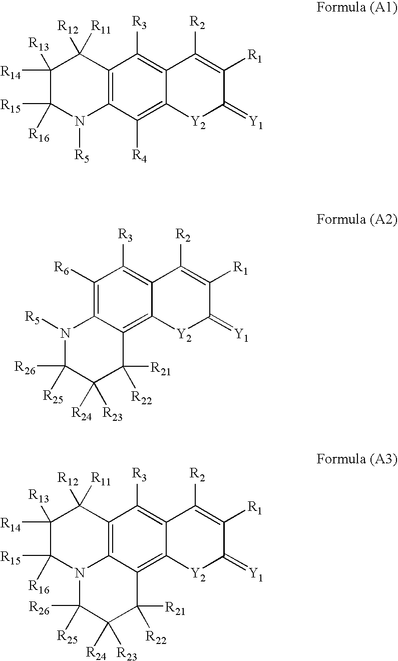

This application is based on Japanese Patent Application No. 2005-083354, which was filed on Mar. 23, 2005 in Japanese Patent Office, the entire content of which is hereby incorporated by reference.

### FIELD OF THE INVENTION

The present invention relates to a photopolymerizable composition, a light sensitive planographic printing plate material, and a process of manufacturing a planographic printing plate, and particularly to a photopolymerizable composition providing high storage stability, high sensitivity and high printing durability, a light sensitive planographic printing plate material employing the photopolymerizable composition, and a process of manufacturing a planographic printing plate from the light sensitive planographic printing plate material.

### BACKGROUND OF THE INVENTION

A planographic printing plate material is well known which comprises a support subjected to hydrophilic treatment and provided thereon, a photopolymerizable layer and a protective layer. Recently, a method of manufacturing a planographic printing plate is carried out which subjects a planographic printing plate material to digital exposure employing a laser based on image information, and developing it, whereby a printing plate with an image of high resolution is obtained at high speed without employing an original film. For example, a process of preparing a planographic printing plate is known which comprises scanning-exposing a planographic printing plate material to light modulated by output signals from an electronic plate making system or an image processing system or by image signals transmitted through channel.

It is generally known that the photopolymerizable layer as described above contains an acryl monomer, an alkali-soluble resin, a photopolymerization initiator, and optionally a sensitizing dye to absorb a range of wavelengths of emitted light for exposure (particularly laser light).

As a light source for exposing a photopolymerization type light sensitive planographic printing plate material is used a visible light source having a longer wavelength such as an Ar laser (488 nm) or an FD-YAG laser (532 nm). In recent years, semiconductor lasers employing, for example, InGaN type material, which can continuously emit light with a wavelength of from 380 to 430 nm, are about to be put into practical use. A scanning exposure system employing light with such a short wavelength as a light source has advantages in providing sufficient output power and an economical system, since the semiconductor lasers can be manufactured at low cost. Further, a light sensitive planographic printing plate material to be applied to the above light source has a spectral sensitivity shorter than that of a planographic printing plate material to be applied to a system employing a conventional FD-YAG laser or Ar laser, and therefore provides an excellent safe light property, whereby operation under room light is easy. For the reasons above, a manufacturing method of a planographic printing plate has been strongly desired in this industry, which employs a relatively short wavelength semiconductor laser with a wavelength of from 350 to 450 nm.

A photopolymerizable composition with high sensitivity to a short wavelength semiconductor laser with a wavelength of 350 to 450 nm containing ketocoumarin compounds as sensitizing dyes is disclosed in Japanese Patent O.P.I. Publication No. 2003-21901. Further, a photopolymerizable composition containing, as a photopolymerization initiator, an iron-arene complex and a halogenated alkyl group-containing compound is disclosed in Japanese Patent O.P.I. Publication No. 2005-18012. However, these compositions do not still provide sufficiently effective performances, and prompt improvement thereof has been required.

### SUMMARY OF THE INVENTION

An object of the invention is to provide a photopolymerizable composition providing high storage stability, high sensitivity and high printing durability, a light sensitive planographic printing plate material employing the photopolymerizable composition, and a process of manufacturing a planographic printing plate from the light sensitive planographic printing plate material.

### DETAILED DESCRIPTION OF THE INVENTION

The present inventor has an extensive study in order to attain the above object. As a result, the inventor has found that a light sensitive planographic printing plate material comprising a combination of a specific photopolymerization initiator provides high sensitivity and high printing durability, and completed the invention. The above object has been achieved by the following constitutions.

The above object has been achieved by any one of the following constitutions.

1. A photopolymerizable composition containing an ethylenically unsaturated monomer, a photopolymerization initiator and a sensitizing dye, wherein the photopolymerization initiator is comprised of an iron-arene compound and a tribromoacetic acid ester having a molecular weight of not less than 500, and the sensitizing dye is at least one selected from the group consisting of compounds represented by the following formulae (A1), (A2) and (A3), 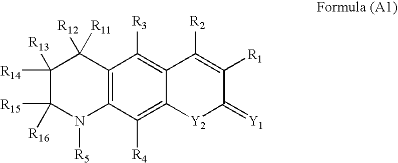
wherein R₁, R₂, R₃, R₄, R₅, R₁₁, R₁₂, R₁₃, R₁₄, R₁₅ and R₁₆ independently represent a hydrogen atom or a substituent, provided that at least one of R₁₁, R₁₂, R₁₃′, R₁₄, R₁₅ and R₁₆ is a substituent; Y₁ represents an oxygen atom or a sulfur atom; and Y₂ represents an oxygen atom or N—R₁₇ in which R₁₇ represents a hydrogen atom or a substituent, 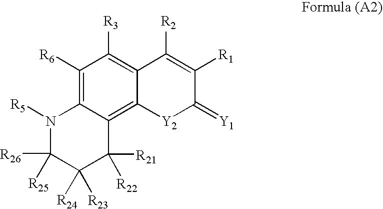
wherein R₁, R₂, R₃, R₅, R₆, R₂₁, R₂₂, R₂₃, R₂₄, R₂₅ and R₂₆ independently represent a hydrogen atom or a substituent, provided that at least one of R₂₁, R₂₂, R₂₃, R₂₄, R₂₅ and R₂₆ is a substituent; Y₁ represents an oxygen atom or a sulfur atom; and Y₂ represents an oxygen atom or N—R₁₇ in which R₁₇ represents a hydrogen atom or a substituent, 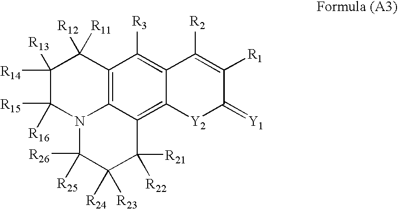
wherein R₁, R₂, R₃, R₁₁, R₁₂, R₁₃, R₁₄, R₅, R₁₆, R₂₁, R₂₂, R₂₃, R₂₄, R₂₅ and R₂₆ independently represent a hydrogen atom or a substituent, provided that at least one of R₁₁, R₁₂, R₁₃, R₁₄, R₁₅, R₁₆, R₂₁, R₂₂, R₂₃, R₂₄, R₂₅ and R₂₆ is a substituent; Y₁ represents an oxygen atom or a sulfur atom; and Y₂ represents an oxygen atom or N—R₁₇ in which R₁₇ represents a hydrogen atom or a substituent.

2. The photopolymerizable composition of item 1 above, wherein the substituent represented by R₁, R₂, R₃, R₄, R₅, R₁₁, R₁₂, R₁₃, R₁₄, R₁₅, R₁₆ and R₁₇ of formula (A1), R₁, R₂, R₃, R₅, R₆, R₁₇, R₂₁, R₂₂, R₂₃, R₂₄, R₂₅ and R₂₆ of formula (A2), and R₁, R₂, R₃, R₁₁, R₁₂, R₁₃, R₁₄, R₁₅, R₁₆, R₁₇, R₂₁, R₂₂, R₂₃, R₂₄, R₂₅ and R₂₆ of Formula (A3)-represents an alkyl group, a cycloalkyl group, an alkenyl group, an alkynyl group, an aryl group, a heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amido group, a carbamoyl group, a ureido group, a sufinyl group, an alkylsulfonyl group, an arylsulfonyl group, an amino group, a halogen atom, a fluorohydrocarbon group, a cyano group, a nitro group, a hydroxyl group, a mercapto group, or a silyl group.

3. The photopolymerizable composition of item 1 above, wherein the tribromoacetic acid ester has a molecular weight of from 500 to 1000, and is represented by formula (B1), 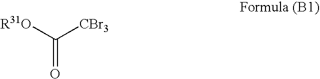
wherein R₃₁ represents an alkyl group, a cycloalkyl group or an alkenyl group.

4. The photopolymerizable composition of item 1 above, wherein the iron arene compound is a compound having the following formula (1), (2) or (3), 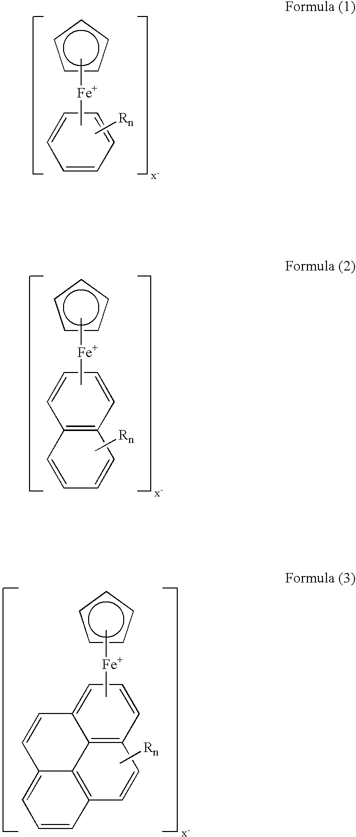
wherein R represents an alkyl group; n represents an integer of from 1 to 4; and X⁻ represents an anionic group, provided that when n is 2 or more, plural R's may be the same or different, and the adjacent two R's may combine with each other to form a ring.

5. The photopolymerizable composition of item 1 above, wherein the photopolymerizable composition further contains a polymeric compound.

6. The photopolymerizable composition of item 5 above, wherein the polymeric compound has an acid value of from 10 to 150.

7. The photopolymerizable composition of item 5 above, wherein the polymeric compound is a polymer having an acryloyl group or a methacryloyl group in the side chain.

8. The photopolymerizable composition of item 1 above, wherein the photopolymerizable composition contains the ethylenically unsaturated monomer in an amount of from 20 to 70% by weight of total solid content of the composition, the photopolymerization initiator in an amount of from 0.1 to 20% by weight of the monomer content, and the sensitizing dye in an amount of from 0.05 to 30% by weight of the monomer content.

9. A light sensitive planographic printing plate material comprising a support, and provided thereon, a photopolymerizable light sensitive layer containing the photopolymerizable composition of item 1 above, wherein the photopolymerizable light sensitive layer further contains a polymeric binder, which is a polymer having an acryloyl group or a methacryloyl group in the polymer side chain.

10. A process of manufacturing a planographic printing plate comprising the step of imagewise scanning-exposing the light sensitive planographic printing plate material of item 9 above to laser beams with a wavelength of from 350 to 450 nm.

The sensitizing dye represented by formulae (A1), (A2) and (A3) will be explained.

In formula (A1), R₁, R₂, R₃, R₄, R₅, R₁₁, R₁₂, R₁₃, R₁₄, R₁₅ and R₁₆ independently represent a hydrogen atom or a substituent, provided that at least one of R₁₁, R₁₂, R₁₃, R₁₄, R₁₅ and R₁₆ is a substituent, and that R₁ and R₂, R₂ and R₃, R₄ and R₅ each may combine with each other to form a ring. Examples of the substituent include an alkyl group (e.g., methyl, ethyl, propyl, isopropyl, tert-butyl, pentyl, hexyl, octyl, dodecyl, tridecyl, tetradecyl, pentadecyl), a cycloalkyl group (e.g., cyclopentyl, cyclohexyl), an alkenyl group (e.g., vinyl, allyl), an alkynyl group (e.g., ethynyl, propargyl), an aryl group (e.g., phenyl, naphthyl), a heterocyclic group (e.g., furyl, thienyl, pyridyl, pyridazyl, pyrimidyl, pyrazyl, triazyl, imidazolyl, pyrazolyl, thiazolyl, benzimidazolyl, benzoxazolyl, quinazolyl, phthalazyl, pyrrolidyl, imidazolidyl, morpholyl group, oxazolidyl), an alkoxy group (e.g., methoxy, ethoxy, propyloxy, pentyloxy, hexyloxy, octyloxy, dodecyloxy), a cycloalkoxy group (e.g., cyclopentyloxy, cyclohexyloxy), an aryloxy group (e.g., phenoxy, naphthyloxy), an alkylthio group (e.g., methylthio, ethylthio, propylthio, pentylthio, hexylthio, octylthio, dodecylthio), a cycloalkylthio group (e.g., cyclopentylthio, cyclohexylthio), an arylthio group (e.g., phenylthio, naphthylthio), an alkoxycarbonyl group (e.g., methyloxycarbonyl, ethyloxycarbonyl, butyloxycarbonyl, octyloxycarbonyl, dodecyloxycarbonyl), an aryloxycarbonyl group (e.g., phenyloxycarbonyl, naphthyloxycarbonyl), a sulfamoyl group (e.g., aminosulfonyl, methylaminosulfonyl, dimethylaminosulfonyl, butylaminosulfonyl, hexylaminosufonyl, cyclohexylaminosulfonyl, octylaminosulfonyl, dodecylaminosulfonyl, phenylaminosulfonyl, naphthylaminosulfonyl, 2-pyridylaminosulfonyl), an acyl group (e.g., acetyl, ethylcarbonyl, propylcarbonyl, pentylcarbonyl, cyclohexylcarbonyl, octylcarbonyl, 2-ethylhexylcarbonyl, dodecylcarbonyl, phenylcarbonyl, naphthylcarbonyl, pyridylcarbonyl), an acyloxy group (e.g., acetyloxy, ethylcarbonyloxy, butylcarbonyloxy, octylcarbonyloxy, dodecylcarbonyloxy, phenylcarbonyloxy), an amido group (e.g., methylcarbonylamino, ethylcarbonylamino, dimethylcarbonylamino, propylcarbonylamino, pentylcarbonylamino, cyclohexylcarbonylamino, 2-ethylhexylcarbonylamino, octylcarbonylamino, dodecylcarbonylamino, phenylcarbonylamino, naphthylcarbonylamino), a carbamoyl group (e.g., aminocarbony, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, 2-pyridylaminocarbonyl), a ureido group (e.g., methylureido, ethylureido, pentylureido, cyclohexylureido, octylureido, dodecylureido, phenylureido, naphthylureido, 2-pyridylureido), a sufinyl group (e.g., methylsulfinyl, ethylsulfinyl, butylsulfinyl, cyclohexylsulfinyl, 2-ethylhexylsulfinyl, dodecysulfinyl, phenylsufinyl, naphthylsulfinyl, 2-pyridylsulfiny), an alkylsulfonyl group (e.g., methylsulfonyl, ethylsulfonyl, butylsulfonyl, cyclohexylsulfonyl, 2-ethylhexylsulfonyl, dodecylsufonyl), an arylsulfonyl group (e.g., phenylsulfonyl, naphthylsulfonyl, 2-pyridylsulfonyl), an amino group (e.g., amino, ethylamino, dimethylamino, butylamino, cyclopentylamino, 2ethylhexylamino, dodecylamino, anilino, naphthylamino, 2-pyridylamino), a halogen atom (e.g., fluorine atom, chlorine atom, bromine atom), a fluorohydrocarbon group (e.g., fluoromethyl, trifluoromethyl, pentafloroethyl, pentafluorophenyl), a cyano group, a nitro group, a hydroxyl group, a mercapto group, and a silyl group (e.g., trimethylsilyl, triisopropylsilyl, triphenylsilyl, phenyldiethylsilyl). The foregoing substituents may have the substituent as denoted above in R¹ through R⁵, and the plural substituents described above adjacent to each other may combine with each other to form a ring.

In formula (A1), R₁ and R₂, R₂ and R₃, and R₄ and R₅ may combine with each other to form a ring. The substituent represented by R₁ is preferably an aryl group, a heterocyclic group, an alkoxycarbonyl group, an aryloxycarbonyl group, an acyl group or a carbamoyl group in view of sensitivity or absorption wavelength. The substituent represented by R₁₁ through R₁₆ is preferably an alkyl group or an aryl group.

Y₁ represents an oxygen atom or a sulfur atom, and is preferably an oxygen atom in view of sensitivity. Y₂ represents an oxygen atom or N—R₁₇ in which R₁₇ represents a hydrogen atom or a substituent. The substituent represented by R₁₇ represents the same as those denoted above in the substituent of R₁ through R₅. Y₂ is preferably is an oxygen atom.

In formula (A2), R₁, R₂, R₃, R₅, R₆, R₂₁, R₂₂, R₂₃, R₂₄, R₂₅ and R₂₆ independently represent a hydrogen atom or a substituent, provided that at least one of R₂₁, R₂₂, R₂₃, R₂₄, R₂₅ and R₂₆ is a substituent, and provided that R₁ and R₂, R₂ and R₃, and R₃ and R₆ may combine with each other to form a ring; Y₁ represents an oxygen atom or a sulfur atom; and Y₂ represents an oxygen atom or N—R₁₇ in which R₁₇ represents a hydrogen atom or a substituent. The substituent represented by R₁, R₂, R₃, R₅, R₆, R₁₇, R₂₁, R₂₂, R₂₃, R₂₄, R₂₅ and R₂₆— in formula (A2) represents the same as those denoted above in the substituent of R₁ through R₅ in formula (A1). The substituent represented by R₂₁ through R₂₆ is preferably an alkyl group or an aryl group.

In formula (A3), R₁, R₂, R₃, R₁₁, R₁₂, R₁₃, R₁₄, R₁₅, R₁₆, R₂₁, R₂₂, R₂₃, R₂₄, R₂₅ and R₂₆ independently represent a hydrogen atom or a substituent, provided that at least one of R₁₁, R₁₂, R₁₃, R₁₄, R₁₅, R₁₆, R₂₁, R₂₂, R₂₃, R₂₄, R₂₅ and R₂₆ is a substituent, and provided that R₁ and R₂, and R₂ and R₃ may combine with each other to form a ring; Y₁ represents an oxygen atom or a sulfur atom; and Y₂ represents an oxygen atom or N—R₁₇ in which R₁₇ represents a hydrogen atom or a substituent. The substituent represented by R₁, R₂, R₃, R₁₁, R₁₂, R₁₃, R₁₄, R₁₅, R₁₆, R₁₇, R₂₁, R₂₂, R₂₃, R₂₄, R₂₅ and R₂₆ in formula (A3) represents the same as those denoted above in the substituent of R₁ through R₅ in formula (A1). The substituent represented by R₁₁ through R₁₆ and R₂₁ through R₂₆ in formula (A3) is preferably an alkyl group or an aryl group.

Among compounds represented by formulae (A1), (A2) and (A3) above, a compound of formula (A) is most preferable.

Examples of the compounds represented by formulae (A1), (A2) and (A3) will be listed below, but the invention is not limited thereto.

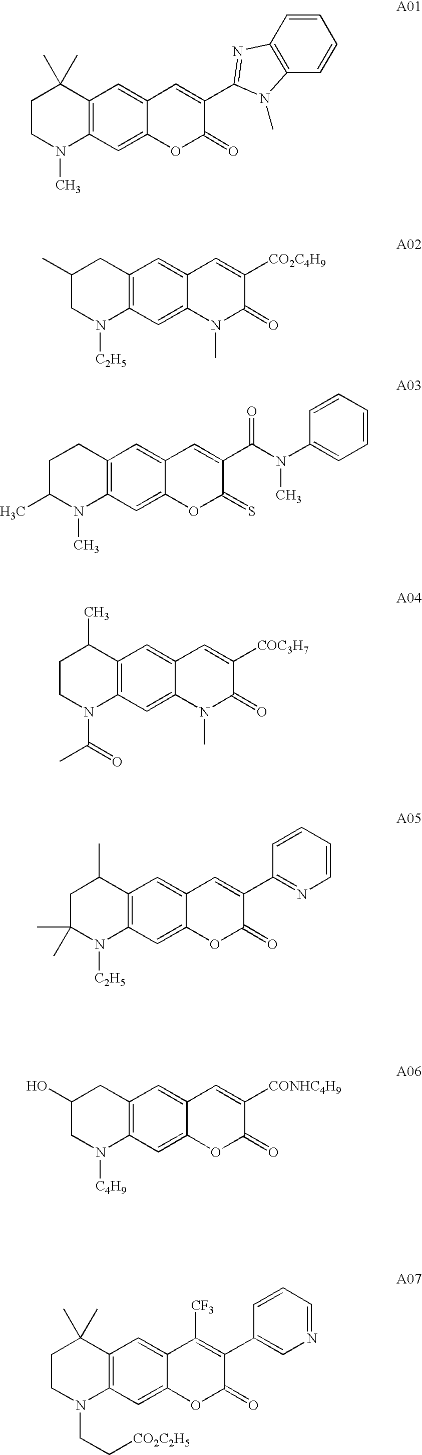

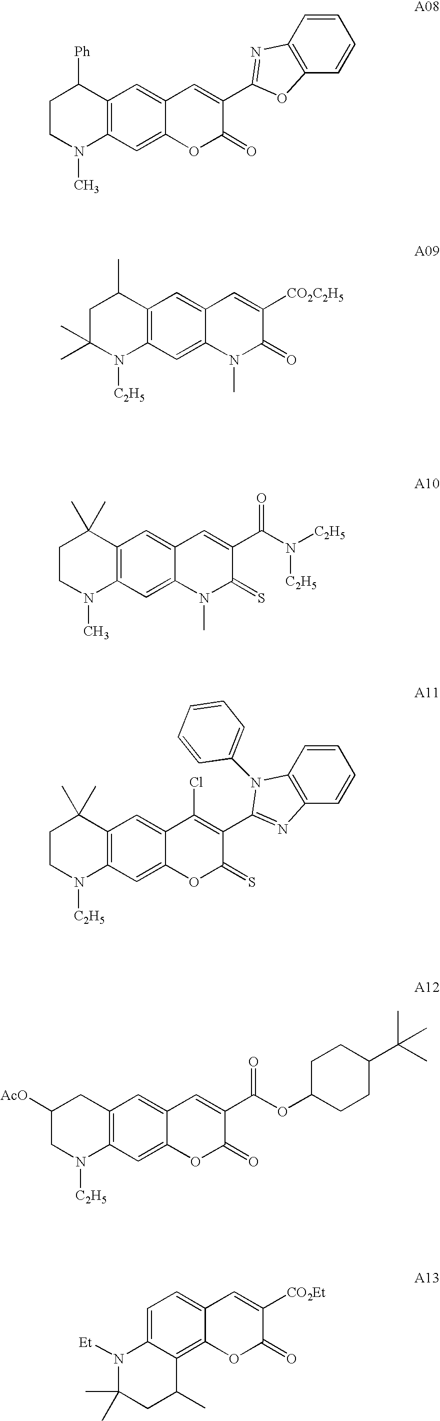

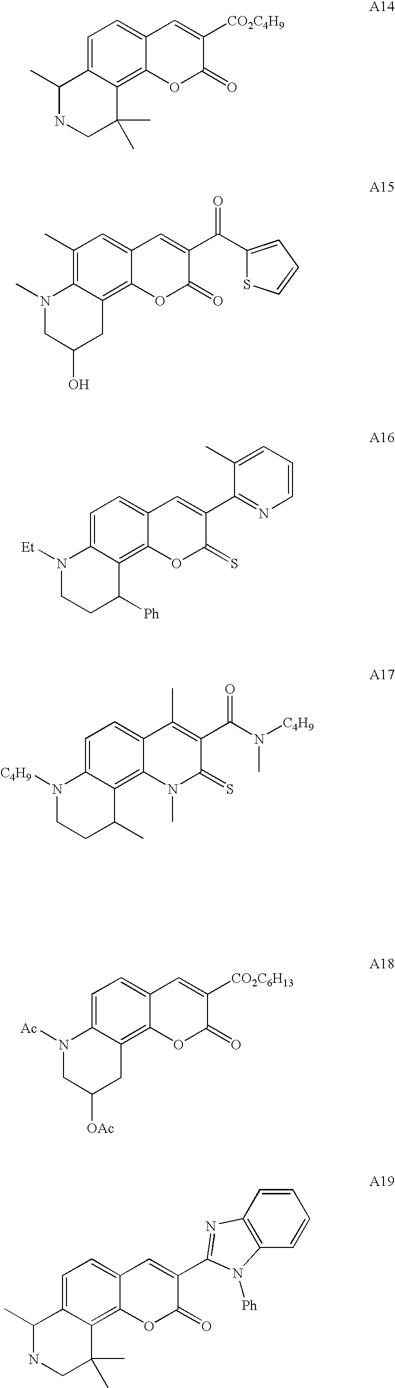

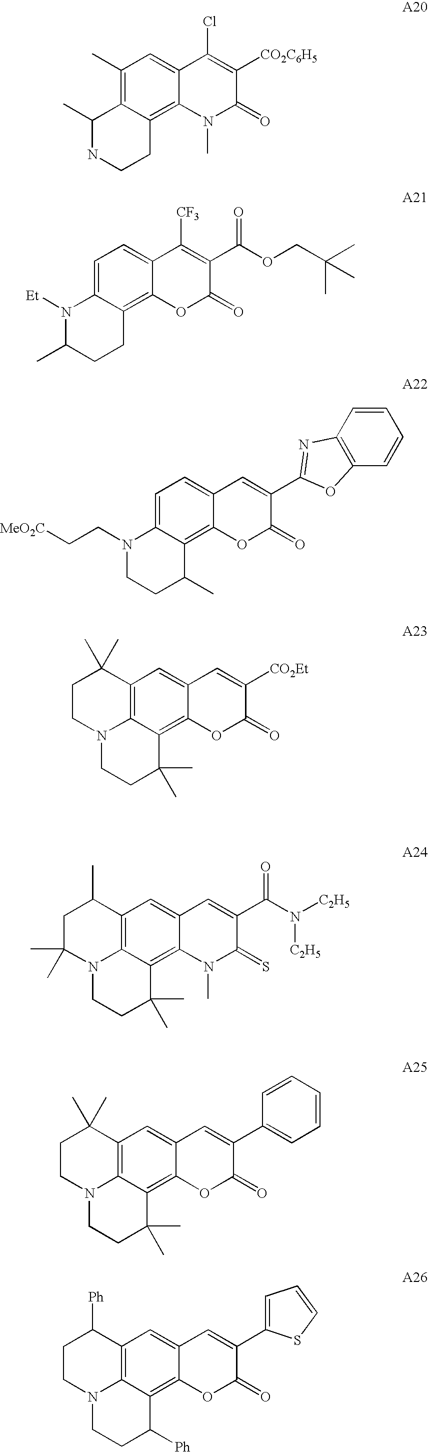

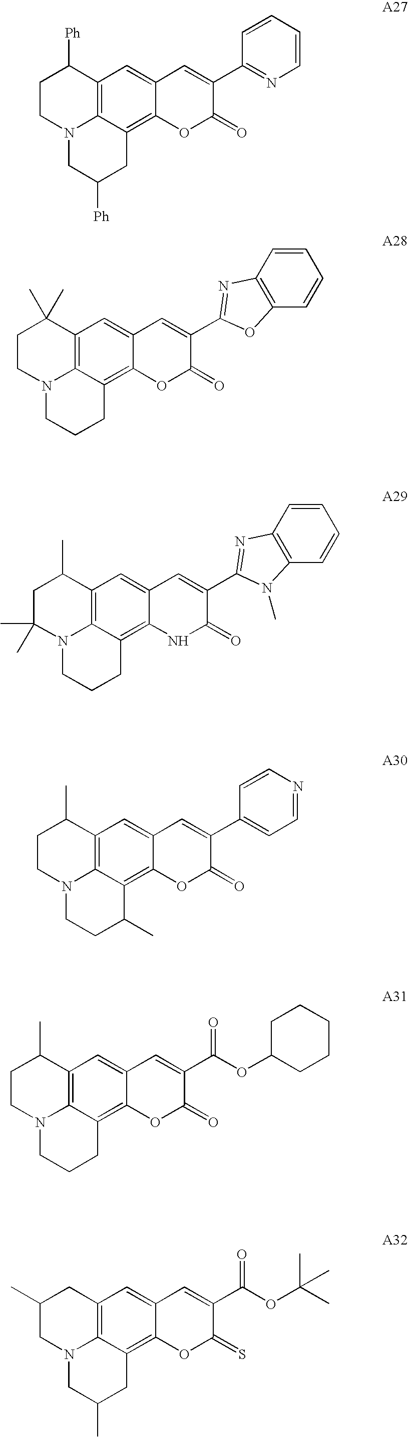

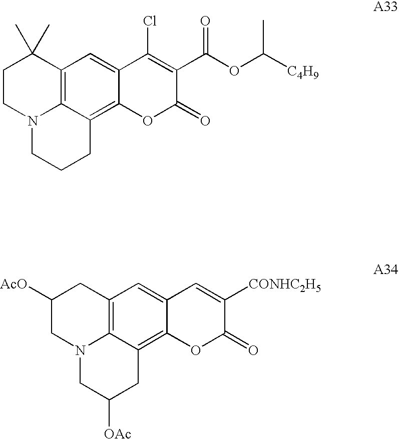

The sensitizing dye in the invention can be easily synthesized according to a conventional synthetic method.

The addition amount of the sensitizing dye in the invention in the photopolymerizable composition is ordinarily from 0.05 to 30 parts by weight, and preferably from 0.1 to 20 parts by weight, based on 100 parts by weight of an ethylenically unsaturated compound described later. The sensitizing dyes in the invention can be used singly or as an admixture of two or more kinds thereof.

The iron arene compound used as a photopolymerization initiator in the invention refers to a compound in which an iron ion combines with π electron of an aromatic hydrocarbon compound, an aromatic heterocyclic compound or an unsaturated compound through a π bonding. The iron arene compound is not specifically limited, and examples thereof include a compound having the following formula (1), (2) or (3).

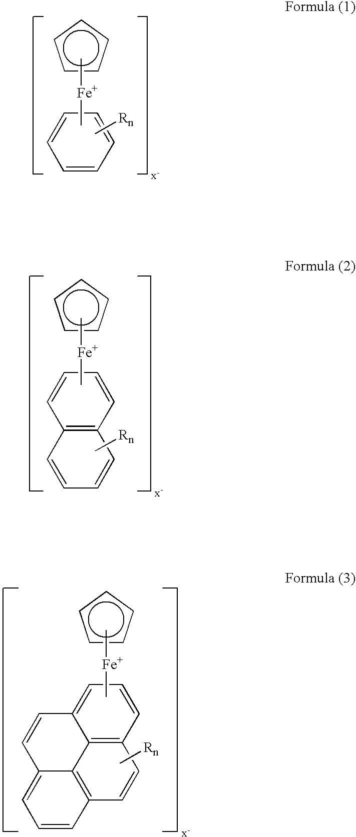

In the formula above, R represents a substituent, preferably an alkyl group, and more preferably an alkyl group having a carbon atom number of from 1 to 5 (for example, methyl, ethyl, n-propyl, i-propyl or n-pentyl); n represents a positive integer, preferably an integer of from 1 to 4; and X⁻ represents an anionic group, provided that when n is 2 or more, plural R's may be the same or different, and the adjacent two R's may combine with each other to form a ring. Examples of X⁻ include PF₆⁻, BF₄⁻, SbF₆⁻, AlF₄⁻, and CF₃SO₃⁻. Preferred examples of the iron-arene complex will be listed below, but the invention is not limited thereto.

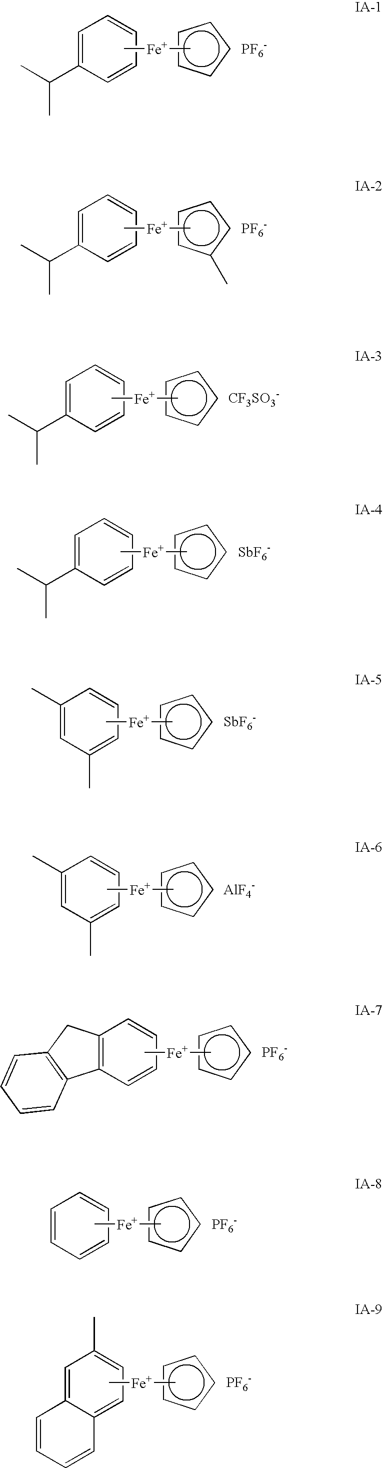

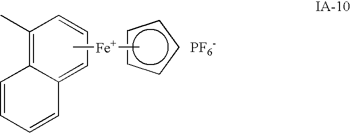

Tribromoacetic acid ester used in the invention as a photopolymerizable initiator has a molecular weight of preferably not less than 500, and preferably from 500 to 1000. Tribromoacetic acid ester used in the invention is preferably a compound represented by the following formula (B1). 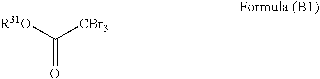
wherein R₃₁ represents those as denoted above in the substituent of R₁ through R₅ of Formula (A1). R₃₁ may further have a substituent, or a condensed ring. R₃₁ is preferably an alkyl group, a cycloalkyl group or alkenyl group, in view of sensitivity.

Next, examples of the compound represented by formula (B1) will be listed, but the invention is not limited thereto.

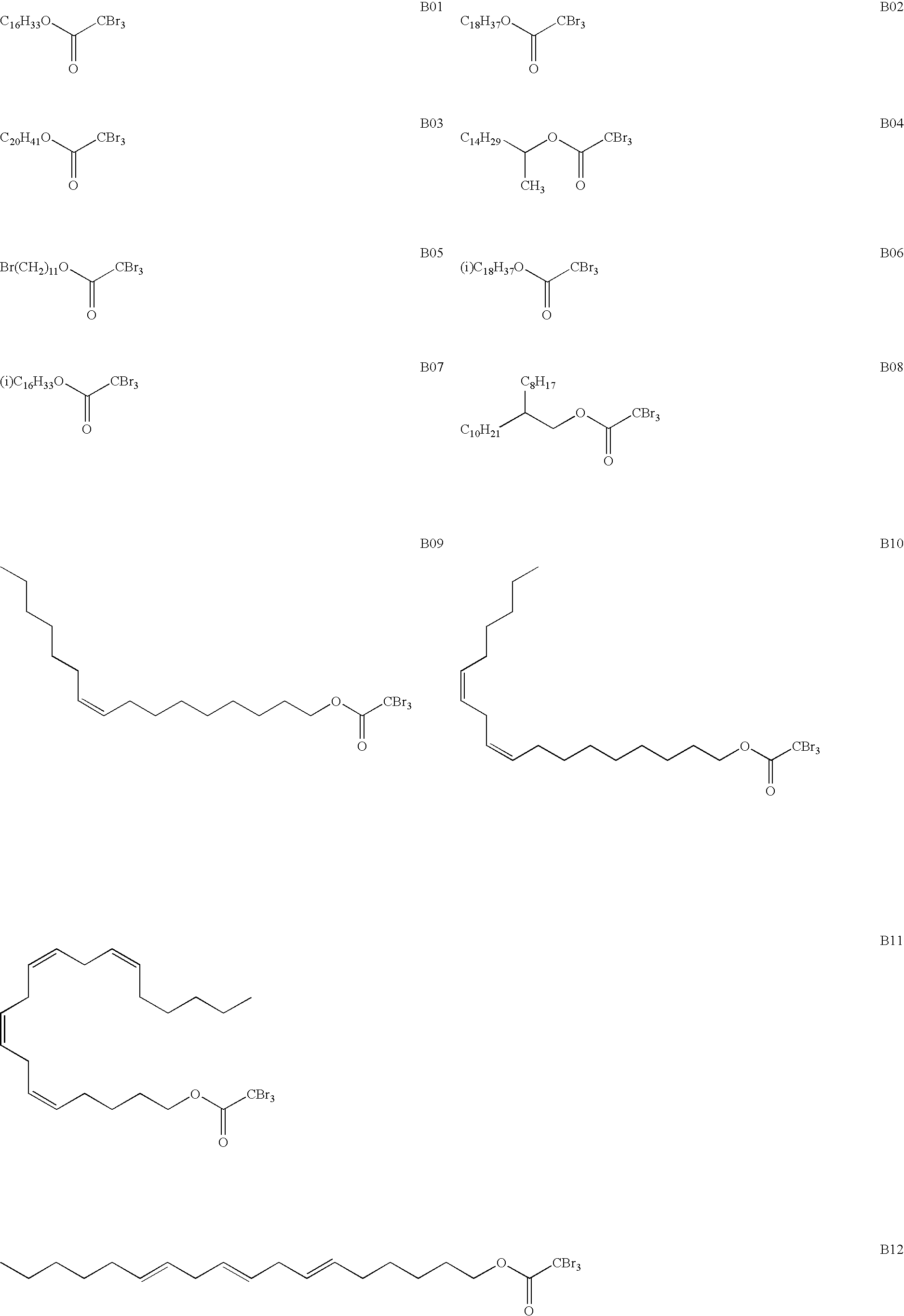

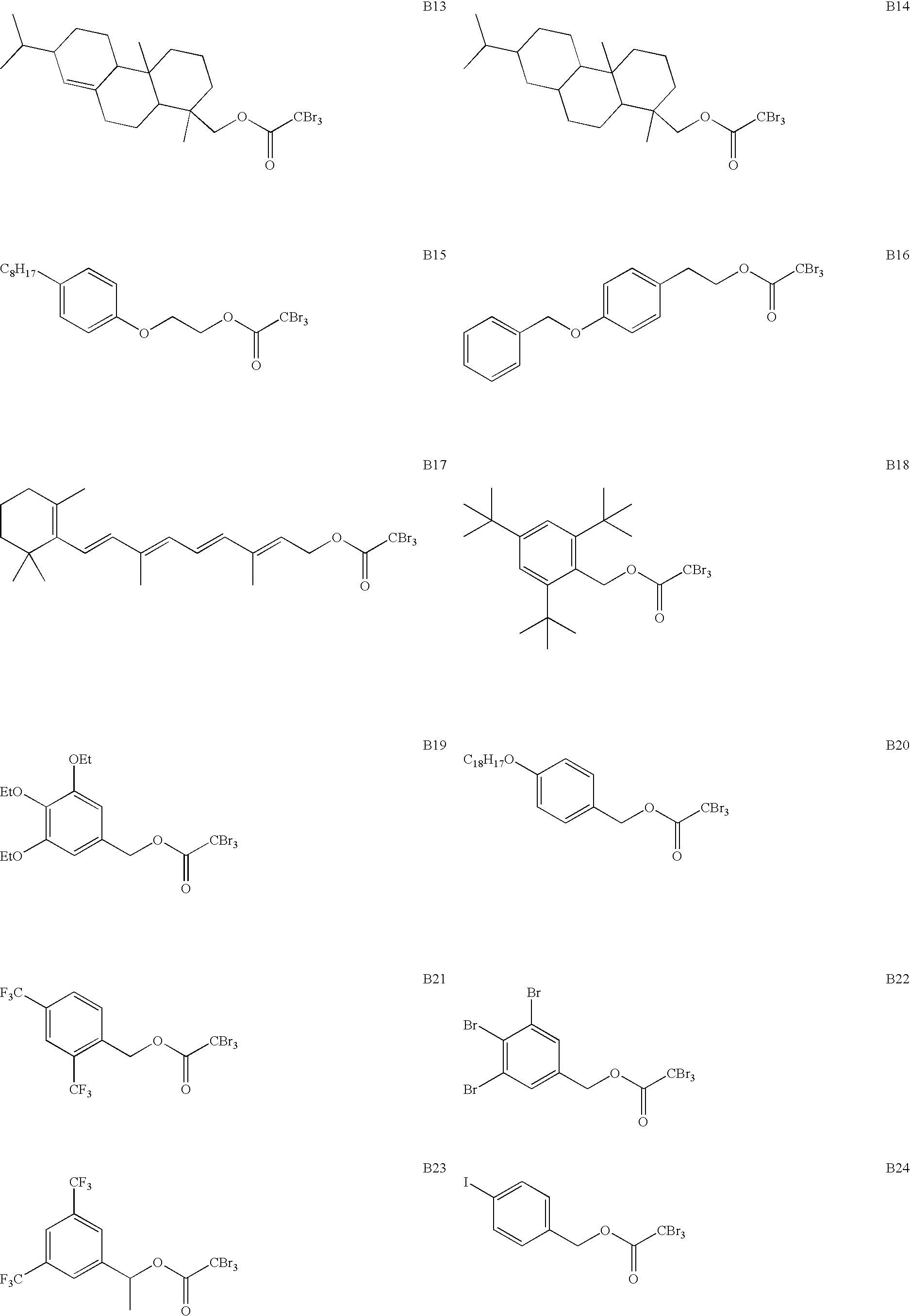

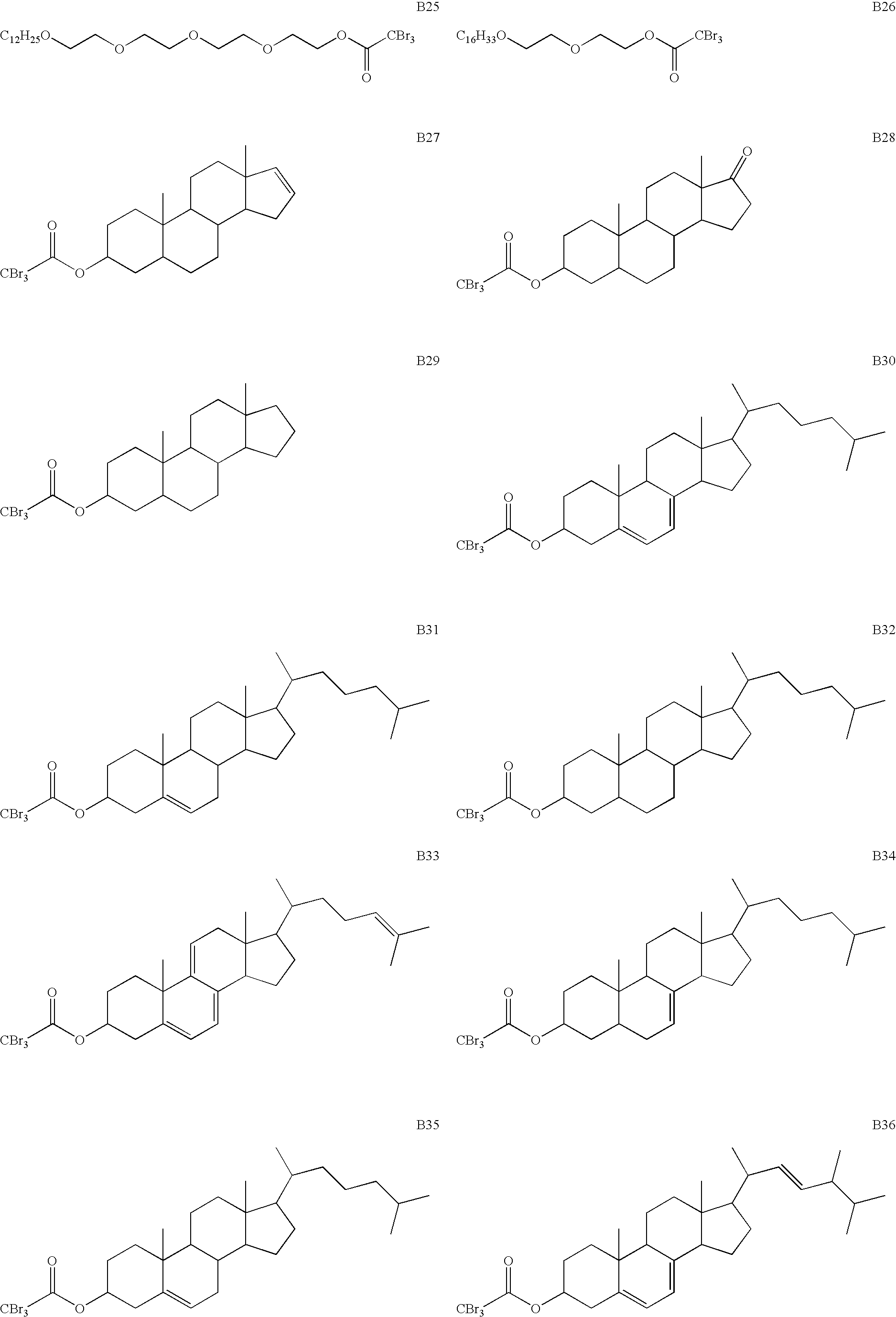

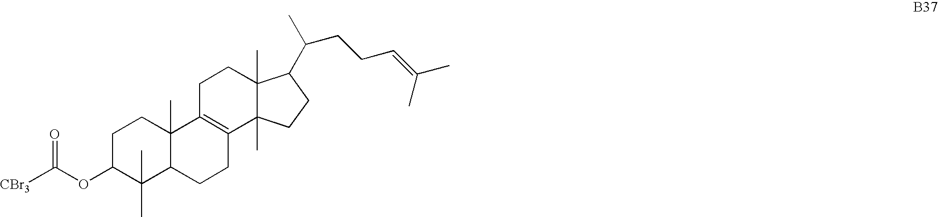

The addition amount of the photopolymerization initiator is preferably 0.1 to 20 parts by weight based on 100 parts by weight of ethylenically unsaturated compound described later, although it is not specifically limited. The content ratio of the photopolymerization initiator to the sensitizing dye in the photopolymerization composition is preferably from 1:100 to 100:1 by mole.

As the addition-polymerizable ethylenically unsaturated compound (hereinafter also referred to as ethylenically unsaturated compound or ethylenically unsaturated monomer) in the invention, there are a conventional radical polymerizable monomer and a polyfunctional monomer or oligomer having two or more of an ethylenic double bond in the molecule as generally used in an ultraviolet curable resin composition.

Such a compound is not specifically limited. Preferred examples thereof include a monofunctional acrylate such as 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryl-oxyethyl acrylate, tetrahydrofurfuryloxyhexanorideacrylate, an ester of 1,3-dioxane-ε-caprolactone adduct with acrylic acid, or 1,3-dioxolane acrylate; a methacrylate, itaconate, crotonate or maleate alternative of the above acrylate; a bifunctional acrylate such as ethylene glycol diacrylate, triethylene glycol diacrylate, pentaerythritol diacrylate, hydroquinone diacrylate, resorcin diacrylate, hexanediol diacrylate, neopentyl glycol diacrylate, tripropylene glycol diacrylate, hydroxypivalic acid neopentyl glycol diacrylate, neopentyl glycol adipate diacrylate, diacrylate of hydroxypivalic acid neopentyl glycol-ε-caprolactone adduct, 2-(2-hydroxy-1,1-dimethylethyl)-5-hydroxymethyl-5-ethyl-1,3-dioxane diacrylate, tricyclodecanedimethylol acrylate, tricyclodecanedimethylol acrylate-s-caprolactone adduct or 1,6-hexanediol diglycidylether diacrylate; a dimethacrylate, diitaconate, dicrotonate or dimaleate alternative of the above diacrylate; a polyfunctional acrylate such as trimethylolpropane triacrylate, ditrimethylolpropane tetraacrylate, trimethylolethane triacrylate, pentaerythritol triacrylate, pentaerythritol tetraacrylate, dipentaerythritol tetraacrylate, dipentaerythritol pentaacrylate, dipentaerythritol hexacrylate, dipentaerythritol hexacrylate-ε-caprolactone adduct, pyrrogallol triacrylate, propionic acid dipentaerythritol triacrylate, propionic acid dipentaerythritol tetraacrylate or hydroxypivalylaldehyde modified dimethylolpropane triacryiate; a methacrylate, itaconate, crotonate or maleate alternative of the above polyfunctional acrylate.

Prepolymers can be used, and the prepolymers can be used singly, in combination, or as an admixture thereof with the above described monomer and/or oligomer.

Examples of the prepolymer include polyester (meth)acrylate obtained by incorporating (meth)acrylic acid in a polyester of a polybasic acid such as adipic acid, trimellitic acid, maleic acid, phthalic acid, terephthalic acid, hymic acid, malonic acid, succinic acid, glutaric acid, itaconic acid, pyromellitic acid, fumalic acid, pimelic acid, sebatic acid, dodecanic acid or tetrahydrophthalic acid with a polyol such as ethylene glycol, ethylene glycol, diethylene glycol, propylene oxide, 1,4-butane diol, triethylene glycol, tetraethylene glycol, polyethylene glycol, grycerin, trimethylol propane, pentaerythritol, sorbitol, 1,6-hexanediol or 1,2,6-hexanetriol; an epoxyacrylate such as bisphenol A•epichlorhydrin-(meth)acrylic acid or phenol novolak•epichlorhydrin•(meth)acrylic acid obtained by incorporating (meth)acrylic acid in an epoxy resin; an urethaneacrylate such as ethylene glycol•adipic acid-tolylenediisocyanate•2-hydroxyethylacrylate, polyethylene glycol•tolylenediisocyanate•2hydroxyethylacrylate, hydroxyethylphthalyl methacrylate•xylenediisocyanate, 1,2-polybutadieneglycol•tolylenediisocyanate-2-hydroxyethylacrylate or trimethylolpropane•propylene glycol•tolylenediisocyanate•2-hydroxyethylacrylate, obtained by incorporating (meth)acrylic acid in an urethane resin; a silicone acrylate such as polysiloxane acrylate, or polysiloxane•diisocyanate•2-hydroxyethylacrylate; an alkyd modified acrylate obtained by incorporating a methacroyl group in an oil modified alkyd resin; and a spirane resin acrylate.

The photopolymerization composition in the invention may contain a monomer such as a phosphazene monomer, triethylene glycol, an EO modified isocyanuric acid diacrylate, an EO modified isocyanuric acid triacrylate, dimethyloltricyclodecane diacrylate, trimethylolpropane acrylate benzoate, an alkylene glycol acrylate, or a urethane modified acrylate, or an addition-polymerizable oligomer or prepolymer having a structural unit derived from the above monomer.

The ethylenic monomer used in the invention is a phosphate compound having at least one (meth)acryloyl group. The phosphate compound is a compound having a (meth)acryloyl group in which at least one hydroxyl group of phosphoric acid is esterified.

Besides the above compounds, compounds disclosed in Japanese Patent O.P.I. Publication Nos. 58-212994, 61-6649, 62-46688, 62-48589, 62-173295, 62-187092, 63-67189, and 1-244891, compounds described on pages 286 to 294 of “11290 Chemical Compounds” edited by Kagakukogyo Nipposha, and compounds described on pages 11 to 65 of “UV-EB Koka Handbook (Materials)” edited by Kobunshi Kankokai can be suitably used. Of these compounds, compounds having two or more acryl or methacryl groups in the molecule are preferable, and those having a molecular weight of not more than 10,000, and preferably not more than 5,000 are more preferable.

In the invention, an ethylenically unsaturated monomer having a tertiary amino group in the molecule is preferably used. Its molecular structure is not limited, but those are preferred in which a tertiary amine having a hydroxyl group is modified with glycidyl methacrylate, methacrylic chloride, or acrylic chloride. Examples thereof include a polymerizable compound disclosed in Japanese Patent O.P.I. Publication Nos. 1-165613, and 1-203413.

A reaction product of (i) a polyhydric alcohol having a tertiary amino group in the molecule, (ii) a diisocyanate, and (iii) a compound having both hydroxyl group and addition polymerizable ethylenically double bond in the molecule is preferably used in the invention.

Examples of the polyhydric alcohol having a tertiary amino group in the molecule include triethanolamine, N-methyldiethanolamine, N-ethyldiethanolamine, N-ethyldiethanolamine, N-n-butyldiethanolamine, N-tert-butyldiethanolamine, N,N-di(hydroxyethyl)aniline, N,N, N′, N′-tetra-2-hydroxypropylethylenediamine, p-tolyldiethanolamine, N,N,N′,N′-tetra-2-hydroxyethylethylenediamine, N,N-bis(2-hydroxypropyl)aniline, allyldiethanolamine, 3-dimethylamino-1,2-propane diol, 3-diethylamino-1,2-propane diol, N,N-di(n-propylamino)-2,3-propane diol, N,N-di(iso-propylamino)-2,3-propane diol, and 3-(N-methyl-N-benzylamino)-1,2-propane diol.

Examples of the diisocyanate include butane-1,4-diisocyanate, hexane-1,6-diisocyanate, 2-methylpentane-1,5-diisocyanate, octane-1,8-diisocyanate, 1,3-diisocyanatomethylcyclohexanone, 2,2,4-trimethylhexane-1,6-diisocyanate, isophorone diisocyanate, 1,2-phenylene diisocyanate, 1,3-phenylene diisocyanate, 1,4-phenylene diisocyanate, tolylene-2,4-diisocyanate, tolylene-2,5-diisocyanate, tolylene-2,6-diisocyanate, 1,3-di(isocyanatomethyl)benzene, and 1,3-bis(1-isocyanato-1-methylethyl)benzene, but the invention is not specifically limited thereto.

Examples of the compound having in the molecule a hydroxyl group and an addition polymerizable ethylenically double bond include compounds MH-1 through MH-13 as shown below, but the invention is not limited thereto.

The chemical structure of MH-1 through MH-13 will be shown below.

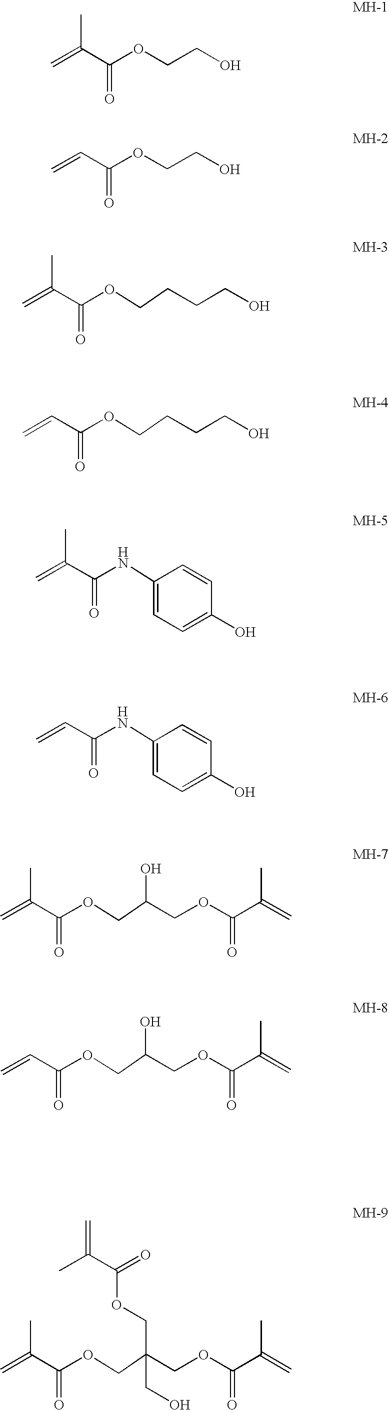

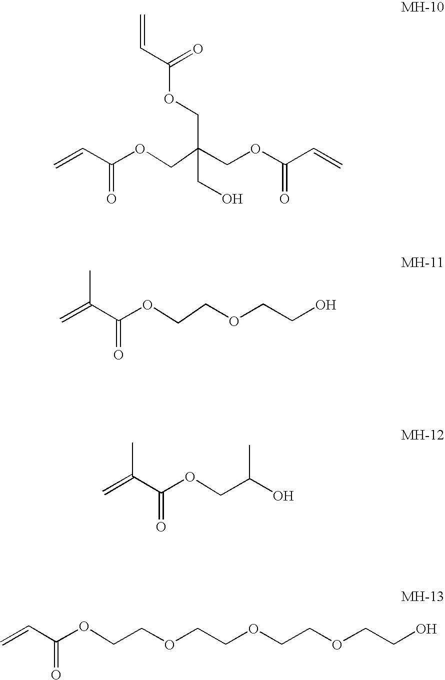

Preferred examples thereof include 2-hydroxyethyl methacrylate, 2-hydroxyethyl acrylate, 4-hydroxybutyl acrylate, 2-hydroxypropylene-1,3-dimethacrylate, and 2-hydroxypropylene-1-methacrylate-3-acrylate.

The reaction product above can be synthesized according to the same method as a conventional method in which a urethaneacrylate compound is ordinarily synthesized employing an ordinary diol, a diisocyanate and an acrylate having a hydroxyl group.

Examples of the reaction product of a polyhydric alcohol having a tertiary amino group in the molecule, a diisocyanate and a compound having a hydroxyl group and an addition polymerizable ethylenically double bond in the molecule will be listed below.

M-1: A reaction product of triethanolamine/hexane-1,6-diisocyanate (3 moles)/2-hydroxyethyl methacrylate (1/3/3 by mole)

M-2: A reaction product of triethanolamine/isophorone diisocyanate/2-hydroxyethyl methacrylate (1/3/3 by mole)

M-3: A reaction product of N-butyldiethanolamine/1,3-bis(1-cyanato-1-methylethyl)benzene/2-hydroxypropylene-1-methacrylate-3-acrylate (1/2/2 by mole)

M-4: A reaction product of N-butyldiethanolamine/1,3-di(cyanatomethyl)benzene/2-hydroxypropylene-1-methacrylate-3-acrylate (1/2/2 by mole)

M-5: A reaction product of N-methydiethanolamine/tolylene-2,4-diisocyanate/2-hydroxypropylene-1,3-dimethacrylate (1/2/2 by mole)

In addition to the above, acrylates or methacrylates disclosed in Japanese Patent O.P.I. Publication Nos. 1-105238 and 2-127404 can be used.

The ethylenically unsaturated compound content of the photopolymerizable composition of the invention is preferably from 20 to 70% by weight, and more preferably from 30 to 60% by weight, based on solid content of the composition.

The photopolymerization composition of the invention contains an ethylenically unsaturated monomer, an iron arene compound, a tribromoacetic acid ester having a molecular weight of not less than 500, and at least one selected from the group consisting of sensitizing dyes represented by formulae (A1), (A2) and (A3). The photopolymerization composition of the invention preferably contains a polymeric binder. As the polymeric binder can be used a polyacrylate resin, a polyvinylbutyral resin, a polyurethane resin, a polyamide resin, a polyester resin, an epoxy resin, a phenol resin, a polycarbonate resin, a polyvinyl butyral resin, a polyvinyl formal resin, a shellac resin, or another natural resin. These resins can be used as an admixture of two or more thereof. The polymeric binder is preferably a vinyl copolymer obtained by copolymerization of an acryl monomer.

The polymeric binder is more preferably a vinyl copolymer obtained by copolymerization of an acryl monomer, and more preferably a copolymer containing (a) a carboxyl group-containing monomer unit and (b) an alkyl methacrylate or alkyl acrylate unit as the copolymerization component.

Examples of the carboxyl group-containing monomer include an α,β-unsaturated carboxylic acid, for example, acrylic acid, methacrylic acid, maleic acid, maleic anhydride, itaconic acid, itaconic anhydride or a carboxylic acid such as a half ester of phthalic acid with 2-hydroxymethacrylic acid.

Examples of the alkyl methacrylate or alkyl acrylate include an unsubstituted alkyl ester such as methylmethacrylate, ethylmethacrylate, propylmethacrylate, butylmethacrylate, amylmethacrylate, hexylmethacrylate, heptylmethacrylate, octylmethacrylate, nonylmethacrylate, decylmethacrylate, undecylmethacrylate, dodecylmethacrylate, methylacrylate, ethylacrylate, propylacrylate, butylacrylate, amylacrylate, hexylacrylate, heptylacrylate, octylacrylate, nonylacrylate, decylacrylate, undecylacrylate, or dodecylacrylate; a cyclic alkyl ester such as cyclohexyl methacrylate or cyclohexyl acrylate; and a substituted alkyl ester such as benzyl methacrylate, 2-chloroethyl methacrylate, N,N-dimethylaminoethyl methacrylate, glycidyl methacrylate, benzyl acrylate, 2-chloroethyl acrylate, N,N-dimethylaminoethyl acrylate or glycidyl acrylate.

The polymeric binder in the invention can further contain, as another co-monomer unit, a monomer unit derived from the monomer described in the following items (1) through (14):

(1) A monomer having an aromatic hydroxy group, for example, o-, (p- or m-) hydroxystyrene, or o-, (p- or m-) hydroxyphenylacrylate;

(2) A monomer having an aliphatic hydroxy group, for example, 2-hydroxyethyl acrylate, 2-hydroxyethyl methacrylate, N-methylolacrylamide, N-methylolmethacrylamide, 4-hydroxybutyl acrylate, 4-hydroxybutyl methacrylate, 5-hydroxypentyl acrylate, 5-hydroxypentyl methacrylate, 6-hydroxyhexyl acrylate, 6-hydroxyhexyl methacrylate, N-(2-hydroxyethyl)acrylamide, N-(2-hydroxyethyl)methacrylamide, or hydroxyethyl vinyl ether;

(3) A monomer having an aminosulfonyl group, for example, m- or p-aminosulfonylphenyl methacrylate, m- or p-aminosulfonylphenyl acrylate, N-(p-aminosulfonylphenyl) methacrylamide, or N-(p-aminosulfonylphenyl)acrylamide;

(4) A monomer having a sulfonamido group, for example, N-(p-toluenesulfonyl)acrylamide, or N-(p-toluenesulfonyl)-methacrylamide;

(5) An acrylamide or methacrylamide, for example, acrylamide, methacrylamide, N-ethylacrylamide, N-hexylacrylamide, N-cyclohexylacrylamide, N-phenylacrylamide, N-nitrophenylacrylamide, N-ethyl-N-phenylacrylamide, N-4-hydroxyphenylacrylamide, or N-4-hydroxyphenylmethacrylamide;

(6) A monomer having a fluorinated alkyl group, for example, trifluoromethyl acrylate, trifluoromethyl methacrylate, tetrafluoropropyl methacrylate, hexafluoropropyl methacrylate, octafluoropentyl acrylate, octafluoropentyl methacrylate, heptadecafluorodecyl methacrylate, heptadecafluorodecyl methacrylate, or N-butyl-N-(2-acryloxyethyl)heptadecafluorooctylsulfonamide;

(7) A vinyl ether, for example, ethyl vinyl ether, 2-chloroethyl vinyl ether, propyl vinyl ether, butyl vinyl ether, octyl vinyl ether, or phenyl vinyl ether;

(8) A vinyl ester, for example, vinyl acetate, vinyl chroloacetate, vinyl butyrate, or vinyl benzoate;

(9) A styrene, for example, styrene, methylstyrene, or chloromethystyrene;

(10) A vinyl ketone, for example, methyl vinyl ketone, ethyl vinyl ketone, propyl vinyl ketone, or phenyl vinyl ketone;

(11) An olefin, for example, ethylene, propylene, isobutylene, butadiene, or isoprene;

(12) N-vinylpyrrolidone, N-vinylcarbazole, or N-vinylpyridine,

(13) A monomer having a cyano group, for example, acrylonitrile, methacrylonitrile, 2-pentenenitrile, 2-methyl-3-butene nitrile, 2-cyanoethyl acrylate, or o-, m- or p-cyanostyrene;

(14) A monomer having an amino group, for example, N,N-diethylaminoethyl methacrylate, N,N-dimethylaminoethyl acrylate, N,N-dimethylaminoethyl methacrylate, polybutadiene urethane acrylate, N,N-dimethylaminopropyl acrylamide, N,N-dimethylacrylamide, acryloylmorpholine, N-isopropylacrylamide, or N,N-diethylacrylamide.

Further, another monomer may be copolymerized with the above monomer.

As the polymeric binder is also preferred an unsaturated bond-containing copolymer which is obtained by reacting a carboxyl group contained in the above vinyl copolymer molecule with for example, a compound having a (meth)acryloyl group and an epoxy group. Examples of the compound having a (meth)acryloyl group and an epoxy group in the molecule include glycidyl acrylate, glycidyl methacrylate and an epoxy group-containing unsaturated compound disclosed in Japanese Patent O.P.I. Publication No. 11-27196.

The polymeric binder has a weight average molecular weight of preferably from 10,000 to 200,000, measured according to gel permeation chromatography (GPC), but the weight average molecular weight is not limited thereto.

The polymeric binder content of the photopolymerizable composition of the invention is preferably from 10 to 90% by weight, and more preferably from 15 to 70% by weight, and still more preferably from 20 to 50% by weight, based on the solid components in the photopolymerizable composition, in view of sensitivity. The polymeric binder content of the photopolymerizable composition of the invention is most preferably from 20 to 50% by weight based on the solid components in the photopolymerizable composition, in view of sensitivity.

(Preparation of Light Sensitive Planographic Printing Plate Material)

The light sensitive planographic printing plate material of the invention is obtained by coating on a support described later a light sensitive layer coating liquid comprising the photopolymerizable composition described above to form a light sensitive layer on the support. Solvents used in the light sensitive layer coating liquid include an alcohol such as sec-butanol, isobutanol, n-hexanol, or benzyl alcohol; a polyhydric alcohol such as diethylene glycol, triethylene glycol, tetraethylene glycol, or 1,5-pentanediol; an ether such as propylene glycol monobutyl ether, dipropylene glycol monomethyl ether, or tripropylene glycol monomethyl ether; a ketone such as diacetone alcohol, methyl ethyl ketone, cyclohexanone, or methyl cyclohexanone; and an ester such as ethyl lactate, butyl lactate, diethyl oxalate, or methyl benzoate.

The coating liquid is coated on a support according to a conventional method, and dried to obtain a light sensitive planographic printing plate material. Examples of the coating method include an air doctor coating method, a blade coating method, a wire bar coating method, a knife coating method, a dip coating method, a reverse roll coating method, a gravure coating method, a cast coating method, a curtain coating method, and an extrusion coating method. The drying temperature of the coated light sensitive layer is preferably from 60 to 160° C., more preferably from 80 to 140° C., and still more preferably from 90 to 120° C.

Further, the polymeric binder used in the invention has an acid value of preferably from 10 to 150, more preferably from 30 to 120, and most preferably from 50 to 90. Such a polymer provides a light sensitive layer comprised of the photopolymerizable composition in which polarity balance is maintained and a coating solution for the light sensitive layer preventing pigment from coagulating.

In the invention, an oxygen shielding layer (protective layer) is preferably provided on the light sensitive layer.

It is preferred that oxygen shielding layer (protective layer) is highly soluble in the developer as described later (generally an alkaline solution). Polyvinyl alcohol or polyvinyl pyrrolidone is preferably used in the protective layer. Polyvinyl alcohol has the effect of preventing oxygen from transmitting and polyvinyl pyrrolidone has the effect of increasing adhesion between the oxygen shielding layer and the image formation layer. Besides the above two polymers, the oxygen shielding layer may contain a water soluble polymer such as polysaccharide, polyethylene glycol, gelatin, glue, casein, hydroxyethyl cellulose, carboxymethyl cellulose, methyl cellulose, hydroxyethyl starch, gum arabic, sucrose octacetate, ammonium alginate, sodium alginate, polyvinyl amine, polyethylene oxide, polystyrene sulfonic acid, polyacrylic acid, or a water soluble polyamide.

The oxygen shielding layer may further contain a surfactant or a matting agent. The oxygen shielding layer is formed, coating on the light sensitive layer a coating solution in which the components described above are dissolved in an appropriate coating solvent, and drying. The main solvent for the coating solution is preferably water, or alcohol such as methanol, ethanol or iso-propanol.

The thickness of the protective layer is preferably 0.1 to 5.0 μm, and more preferably 0.5 to 3.0 μm.

A support used in the light sensitive planographic printing plate material of the invention is a plate or a sheet capable of carrying the light sensitive layer and preferably has a hydrophilic surface on the side on which the light sensitive layer is to be provided.

As the support used in the invention, a plate of a metal such as aluminum, stainless steel, chromium or nickel, or a plastic film such as a polyester film, a polyethylene film or a polypropylene film, which is deposited or laminated with the above-described metal can be used. Further, a polyester film, a polyvinyl chloride film or a nylon film whose surface is subjected to hydrophilization treatment can be used. Among the above, the aluminum plate is preferably used, and may be a pure aluminum plate or an aluminum alloy plate. As the aluminum alloy, there can be used various ones including an alloy of aluminum and a metal such as silicon, copper, manganese, magnesium, chromium, zinc, lead, bismuth, nickel, titanium, sodium or iron. In the aluminum plate for the support, the surface is roughened for water retention.

When the aluminum plate is used as the support, it is preferable that the aluminum plate is subjected to degreasing treatment for removing rolling oil prior to surface roughening (graining). The degreasing treatments include degreasing treatment employing solvents such as trichlene and thinner, and an emulsion degreasing treatment employing an emulsion such as kerosene or triethanol. It is also possible to use an aqueous alkali solution such as caustic soda for the degreasing treatment. When an aqueous alkali solution such as caustic soda is used for the degreasing treatment, it is possible to remove soils and an oxidized film which can not be removed by the above-mentioned degreasing treatment alone. When an aqueous alkali solution such as caustic soda is used for the degreasing treatment, the resulting plate is preferably subjected to desmut treatment in an aqueous solution of an acid such as phosphoric acid, nitric acid, sulfuric acid, chromic acid or a mixture thereof, in order to remove smuts produced on the surface thereof.

The surface roughening methods include a mechanical surface roughening method and an electrolytic surface roughening method electrolytically etching the support surface. Though there is no restriction for the mechanical surface roughening method, a brushing roughening method and a honing roughening method are preferable.

Though there is no restriction for the electrolytic surface roughening method, a method, in which the aluminum plate is electrolytically surface roughened in an acidic electrolytic solution, is preferred. After the plate has been electrolytically surface roughened, it is preferably dipped in an acid or an aqueous alkali solution in order to remove aluminum dust, etc. produced on the surface. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used. The dissolution amount of aluminum in the aluminum plate surface is preferably 0.5 to 5 g/m². After the aluminum plate has been dipped in the aqueous alkali solution, it is preferably dipped in an acid such as phosphoric acid, nitric acid, sulfuric acid and chromic acid, or in a mixed acid thereof, for neutralization.

The mechanical surface roughening and electrolytic surface roughening may be carried out singly, and the mechanical surface roughening followed by the electrolytic surface roughening may be carried out.

After the surface roughening, anodizing treatment may be carried out. There is no restriction in particular for the method of anodizing treatment used in the invention, and known methods can be used. The anodizing treatment forms an anodization film on the surface of the aluminum plate.

The aluminum plate, which has been subjected to anodizing treatment, is optionally subjected to sealing treatment. For the sealing treatment, it is possible to use known methods using hot water, boiling water, steam, a sodium silicate solution, an aqueous dichromate solution, a nitrite solution and an ammonium acetate solution.

After the above treatment, the aluminum plate is suitably undercoated with a water soluble resin such as polyvinyl phosphonic acid, a polymer or copolymer having a sulfonic acid in the side chain, or polyacrylic acid; a water soluble metal salt such as zinc borate; a yellow dye; an amine salt; and so on, for hydrophilization treatment. The sol-gel treatment support disclosed in Japanese Patent O.P.I. Publication No. 5-304358, which has a functional group capable of causing addition reaction by radicals as a covalent bond, is suitably used.

(Preparation of Planographic Printing Plate)

The light sensitive planographic printing plate material of the invention is imagewise exposed and developed with a developer described later to prepare a planographic printing plate applied to printing.

(Imagewise Exposure)

As a light source for recording an image on the light sensitive planographic printing plate material of the invention (imagewise exposure), a laser with an emission wavelength of from 350 to 450 nm is preferred.

Examples of light sources for imagewise exposure of the light sensitive planographic printing plate material include a He—Cd laser (441 nm), a combination of Cr:LiSAF and SHG crystals (430 nm) as a solid laser, and KnbO3, ring resonator (430 nm), AlGaInN (350-350 nm) or AlGaInN semiconductor laser (InGaN type semiconductor laser available on the market, 400-410 nm) as a semiconductor type laser.

When a laser is used for exposure, which can be condensed in the beam form, scanning exposure according to an image can be carried out, and direct writing is possible without using any mask material. When the laser is employed for imagewise exposure, a highly dissolved image can be obtained, since it is easy to condense its exposure spot in minute size.

As a laser scanning method by means of a laser beam, there are a method of scanning on an outer surface of a cylinder, a method of scanning on an inner surface of a cylinder and a method of scanning on a plane. In the method of scanning on an outer surface of a cylinder, laser beam exposure is conducted while a drum around which a recording material is wound is rotated, in which main scanning is represented by the rotation of the drum, while sub-scanning is represented by the movement of the laser beam. In the method of scanning on an inner surface of a cylinder, a recording material is fixed on the inner surface of a drum, a laser beam is emitted from the inside, and main scanning is carried out in the circumferential direction by rotating a part of or an entire part of an optical system, while sub-scanning is carried out in the axial direction by moving straight a part of or an entire part of the optical system in parallel with a shaft of the drum. In the method of scanning on a plane, main scanning by means of a laser beam is carried out through a combination of a polygon mirror, a galvano mirror and an Fθ lens, and sub-scanning is carried out by moving a recording medium. The method of scanning on an outer surface of a cylinder and the method of scanning on an inner surface of a cylinder are suitable for high density image recording, since it is easier to increase accuracy of an optical system. In the invention, imagewise exposure is carried out at a plate surface energy (an exposure energy at the surface of the planographic printing plate material) of from 10 to 500 mJ/cm², and more preferably from 10 to 300 mJ/cm². This exposure energy can be measured, employing a laser power meter PDGDO-3W produced by Ophir Optronics Inc.

(Development)

The imagewise exposed light sensitive planographic printing plate material, whose light sensitive layer has been cured at exposed portions, is developed with an alkali developer, whereby the light sensitive layer at unexposed portions (non-image portions) are removed to form an image.

As the alkali developer, a conventional alkali aqueous solution is used. For example, there is an alkali developer containing an inorganic alkali agent such as sodium silicate, potassium silicate, ammonium silicate, sodium secondary phosphate, potassium secondary phosphate, ammonium secondary phosphate; sodium hydrogen carbonate, potassium hydrogen carbonate, ammonium hydrogen carbonate; sodium carbonate, potassium carbonate, ammonium carbonate; sodium borate, potassium borate, lithium borate; sodium hydroxide, potassium hydroxide, and ammonium hydroxide.

The alkali developer can contain organic alkali agents such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, and pyridine.

These alkali agents can be used singly or as a mixture of two or more thereof. The alkali developer can contain an anionic surfactant, an amphoteric surfactant, or an organic solvent such as alcohol.

### EXAMPLES

Next, the present invention will be explained in the following examples, but the present invention is not limited thereto. In the examples, “parts” represents. “parts by weight”, unless otherwise specified.

<Synthesis of Acryl Copolymer 1>

Thirty parts of methacrylic acid, 50 parts of methyl methacrylate, 20 parts of ethyl methacrylate, 500 parts of isopropyl alcohol, and 3 parts of α,α′-azobisisobutyro-nitrile were put in a three neck flask under nitrogen atmosphere, and reacted under nitrogen atmosphere for 6 hours at 80° C. in an oil bath. After that, the reaction mixture was refluxed at a boiling point of isopropyl alcohol for one hour, and 3 parts of triethylbenzylammonium chloride and 25 parts of glycidyl methacrylate were further added to the mixture, and reacted for additional 3 hours. Thus, acryl copolymer 1 was obtained. The weight average molecular weight of the acryl copolymer 1 was 35,000, measured according to GPC. The glass transition temperature Tg of the acryl copolymer 1 was 85° C., measured according to DSC (differential thermal analysis).

<Preparation of Support>

A 0.3 mm thick aluminum plate (material 1050, refining H16) was degreased at 60° C. for one minute in a 5% sodium hydroxide solution, washed with water, immersed at 25° C. for one minute in 10% hydrochloric acid solution to neutralize, and then washed with water. The resulting aluminum plate was electrolytically etched using an alternating current at 25° C. for 60 seconds at a current density of 100 A/dm² in an aqueous 0.3% nitric acid solution, and desmut at 60° C. for 10 seconds in a 5% sodium hydroxide solution. The desmut aluminum plate was anodized at 25° C. for 1 minute at a current density of 10 A/dm² and at a voltage of 15 V in a 15% sulfuric acid solution, and further subjected to hydrophilization treatment at 75° C. in an aqueous 1% polyvinyl phosphonic acid solution. Thus, support was obtained.

The center line average surface roughness (Ra) of the support was 0.65 μm.

<Preparation of Planographic Printing Plate Material Sample>

The following photopolymerizable light sensitive layer coating solution 1 was coated on the support above through a wire bar, and dried at 95° C. for 1.5 minutes to give a light sensitive layer having a dry thickness of 2.0 g/m².

(Photopolymerizable Light Sensitive Layer Coating Solution)

| Addition-polymerizable | amount as shown in Table 1 | |
|---|---|---|
| ethylenically unsaturated monomer | | |
| (as shown in Table 1) | | |
| Photopolymerization initiator | amount as shown in Table 1 | |
| (as shown in Table 1) | | |
| Sensitizing dye | amount as shown in Table 1 | |
| (as shown in Table 1) | | |
| Acryl copolymer 1 | 40.0 | parts |
| N-Phenylglycin benzyl ester | 4.0 | parts |
| Phthalocyanine pigment | 6.0 | parts |
| (MHI 454 produced by Mikuni | | |
| Sikisosha) | | |
| 2-t-Butyl-6-(3-t-butyl-2-hydroxy-5- | 0.5 | parts |
| methylbenzyl)-4- | | |
| methylphenylacrylate | | |
| (Sumirizer GS: produced by | | |
| Sumitomo 3M Co., Ltd.) | | |
| Fluorine-contained surfactant | 0.5 | parts |
| (F-178K: produced by Dainippon | | |
| Ink Co., Ltd.) | | |
| Methyl ethyl ketone | 80 | parts |
| Cyclohexanone | 820 | parts |

Subsequently, the following oxygen-shielding layer coating solution was coated on the resulting light sensitive layer through an applicator, and dried at 75° C. for 1.5 minutes to give an oxygen-shielding layer. Thus, light sensitive planographic printing plate material samples 1 through 13 were prepared.

(Oxygen-Shielding Layer Coating Solution)

| | | |
|---|---|---|
| Polyvinyl alcohol, GL-05 | 89 | parts |
| (produced by Nippon Gosei Kagaku Co., Ltd.) | | |
| Water-soluble polyamide P-70 | 10 | parts |
| (produced by Toray Co., Ltd.) | | |
| Surfactant Surfinol 465 | 0.5 | parts |
| (produced by Nisshin Kagaku Kogyo Co., Ltd.) | | |
| Water | 900 | parts |

<Preparation and Evaluation of Light Sensitive Planographic Printing Plate Samples>

Each of the light sensitive planographic printing plate samples obtained above was imagewise exposed at a resolving degree of 2400 dpi, employing a modified plate setter of a plate setter Tiger Cat (produced by ECRM Co., Ltd.) equipped with a laser with an output power of 30 mW emitting light with a wavelength of 408 nm. Herein, dpi represents the dot numbers per 2.54 cm.

An original image used for exposure had a solid image and a 50% square dot image with a screen line number of 175 LPI (line per inch). Subsequently, the exposed sample was subjected to development treatment employing a CTP automatic developing machine (PHW 32-V produced by Technigraph Co., Ltd.) to obtain a planographic printing plate sample. Herein, the developing machine comprised a preheating section for preheating the exposed sample, a pre-washing section for removing the protective layer before development, a development section charged with developer having the following developer composition, a washing section for removing the developer remaining on the developed sample after development, and a gumming section charged with a gumming solution (absolution obtained by diluting GW-3, produced by Mitsubishi Chemical Co., Ltd., with water by a factor of 2) for protecting the surface of the developed sample. Herein, preheating was carried out at 105° C. for 10 seconds. Thus, planographic printing plate samples were obtained.

<Composition of Developer>

| | | |
|---|---|---|
| Potassium silicate A | 8.0 | parts |
| (an aqueous potassium silicate solution | | |
| containing 25.5-27.5% by weight of | | |
| SiO₂ and 12.5-14.5% by weight of K₂O) | | |
| NEWCOL B-13SN (produced | 3.0 | parts |
| by Nippon Nyukazai Co., Ltd.) | | |

| | |
|---|---|
| Potassium hydroxide | Amount giving pH 12.3 |

<<Sensitivity>>

The lowest exposure energy (μJ/cm2), at which no layer reduction was observed at the solid image portions of the planographic printing plate sample, was evaluated as a measure of sensitivity. The less the exposure energy is, the higher the sensitivity.

<<Printing Durability>>

The planographic printing plate material sample was exposed at 200 μJ/cm² and developed to prepare a planographic printing plate sample with a 175 line image. Subsequently, the resulting printing plate sample was mounted on a press (DAIYA1F-1 produced by Mitsubishi Jukogyo Co., Ltd.), and printing was carried out wherein coated paper, printing ink (Soybean oil ink, “Naturalith 100” produced by Dainippon Ink Kagaku Co., Ltd.), and dampening water (SG-51, H solution produced by Tokyo Ink Co., Ltd., Concentration: 1.5%) were used. The number (lowest) of prints printed from when printing started till when dot area reduction of dots at highlight portions was observed was evaluated as a measure of printing durability. The more the number are, the higher the printing durability.

<<Storage Stability>

The light sensitive planographic printing plate material sample obtained above was stored at 55° C. and 20% RH for three days, and then was evaluated for sensitivity in the same manner as described above.

The results are shown in Table 1.

TABLE 1

| | | | Photopolymerization | | | | | |
|---|---|---|---|---|---|---|---|---|
| | Ethylenically | | initiator | | | | | |
| Sample | unsaturated | Sensitizing | Initiator 1 | Initiator 2 | | | | |
| No. | monomer (parts) | dye (parts) | (parts) | (parts) | a) | b) | c) | Remarks |
| 1 | M-3 (25) | A05 | I-1 | B02 | 40 | 5 | 180,000 | Inv. |
| | NK ESTER 4G (15) | (3.0) | (3.0) | (3.0) | | | | |
| 2 | M-3 (25) | A08 | I-1 | B06 | 45 | 5 | 160,000 | Inv. |
| | NK ESTER 4G (15) | (3.0) | (3.0) | (3.0) | | | | |
| 3 | M-3 (25) | A11 | I-1 | B10 | 50 | 5 | 140,000 | Inv. |
| | NK ESTER 4G (15) | (3.0) | (3.0) | (3.0) | | | | |
| 4 | M-3 (25) | A16 | I-1 | B15 | 50 | 10 | 130,000 | Inv. |
| | NK ESTER 4G (15) | (3.0) | (3.0) | (3.0) | | | | |
| 5 | M-3 (25) | A021 | I-1 | B22 | 60 | 10 | 120,000 | Inv. |
| | NK ESTER 4G (15) | (3.0) | (3.0) | (3.0) | | | | |
| 6 | M-3 (25) | A23 | I-1 | B26 | 55 | 10 | 130,000 | Inv. |
| | NK ESTER 4G (15) | (3.0) | (3.0) | (3.0) | | | | |
| 7 | M-3 (25) | A28 | I-1 | B29 | 40 | 5 | 180,000 | Inv. |
| | NK ESTER 4G (15) | (3.0) | (3.0) | (3.0) | | | | |
| 8 | M-3 (25) | A31 | I-1 | B35 | 35 | 5 | 200,000 | Inv. |
| | NK ESTER 4G (15) | (3.0) | (3.0) | (3.0) | | | | |
| 9 | M-3 (25) | A32 | I-1 | BR-1 | 80 | 20 | 80,000 | Comp. |
| | NK ESTER 4G (15) | (3.0) | (3.0) | (3.0) | | | | |
| 10 | M-3 (25) | A32 | I-1 | None | 130 | 30 | 30,000 | Comp. |
| | NK ESTER 4G (15) | (3.0) | (3.0) | | | | | |
| 11 | M-3 (25) | A32 | None | B31 | No image | — | — | Comp. |
| | NK ESTER 4G (15) | (3.0) | | (3.0) | formed | | | |
| 12 | M-3 (25) | D-1 | I-1 | B31 | 100 | 30 | 60,000 | Comp. |
| | NK ESTER 4G (15) | (3.0) | (3.0) | (3.0) | | | | |
| 13 | M-3 (25) | A32 | I-1 | B31 | 35 | 5 | 200,000 | Inv. |
| | NK ESTER 4G (15) | (3.0) | (3.0) | (3.0) | | | | |

Inv.: Inventive,
Comp.: Comparative
NK ESTER 4G: Polyethylene glycol dimethacrylate produced by Shin-Nakamura Kagaku Co.,
Ltd.
a) Exposure energy (μJ/cm²)
b) Exposure energy after 3 days' storage at 55° C. and 20% RH (μJ/cm²)
c) Printing durability (Number)

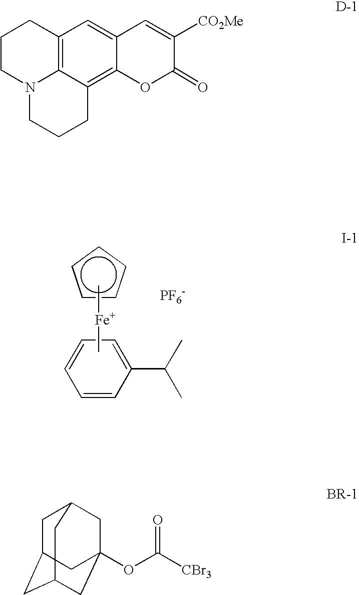

As is apparent from Table 1 above, the inventive light sensitive planographic printing plate material samples provide high storage stability and high sensitivity, and the inventive planographic printing plate samples obtained from the inventive light sensitive planographic printing plate material samples provide high printing durability.

What is claimed is:

1. A photopolymerizable composition containing an ethylenically unsaturated monomer, a photopolymerization initiator and a sensitizing dye, wherein the photopolymerization initiator is comprised of an iron-arene compound and a tribromoacetic acid ester having a molecular weight of not less than 500, and the sensitizing dye is at least one selected from the group consisting of compounds represented by the following formulae (A1), (A2) and (A3), 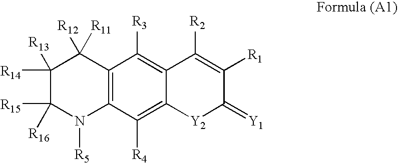
wherein R₁, R₂, R₃, R₄, R₅, R₁₁, R₁₂, R₁₃, R₁₄, R₁₅ and R₁₆ independently represent a hydrogen atom or a substituent, provided that at least one of R₁₁, R₁₂, R₁₃, R₁₄, R₁₅ and R₁₆ is a substituent; Y₁ represents an oxygen atom or a sulfur atom; and Y₂ represents an oxygen atom or N—R₁₇ in which R₁₇ represents a hydrogen atom or a substituent, 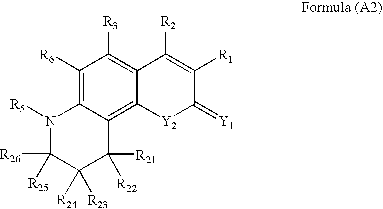
wherein R₁, R₂, R₃, R₅, R₆, R₂₁, R₂₂, R₂₃, R₂₄, R₂₅ and R₂₆ independently represent a hydrogen atom or a substituent, provided that at least one of R₂₁, R₂₂, R₂₃, R₂₄, R₂₅ and R₂₆ is a substituent; Y₁ represents an oxygen atom or a sulfur atom; and Y₂ represents an oxygen atom or N—R₁₇ in which R₁₇ represents a hydrogen atom or a substituent, 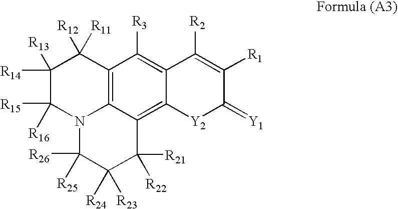
wherein R₁, R₂, R₃, R₁₁, R₁₂, R₁₃, R₁₄, R₁₅, R₁₆, R₂₁, R₂₂, R₂₃, R₂₄, R₂₅ and R₂₆ independently represent a hydrogen atom or a substituent, provided that at least one of R₁₁, R₁₂, R₁₃, R₁₄, R₁₅, R₁₆, R₂₁, R₂₂, R₂₃, R₂₄, R₂₅ and R₂₆ is a substituent; Y₁ represents an oxygen atom or a sulfur atom; and Y₂ represents an oxygen atom or N—R₁₇ in which R₁₇ represents a hydrogen atom or a substituent.

2. The photopolymerizable composition of claim 1, wherein the substituent represented by R₁, R₂, R₃, R₄, R₅, R₁₁, R₁₂, R₁₃, R₁₄, R₁₅, R₁₆ and R₁₇ of formula (A1), R₁, R₂, R₃, R₅, R₆, R₁₇, R₂₁, R₂₂, R₂₃, R₂₄, R₂₅ and R₂₆ of formula (A2), and R₁, R₂, R₃, R₁₁, R₁₂, R₁₃, R₁₄, R₁₅, R₁₆, R₁₇, R₂₁, R₂₂, R₂₃, R₂₄, R₂₅ and R₂₆ of Formula (A3) represents an alkyl group, a cycloalkyl group, an alkenyl group, an alkynyl group, an aryl group, a heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amido group, a carbamoyl group, a ureido group, a sufinyl group, an alkylsulfonyl group, an arylsulfonyl group, an amino group, a halogen atom, a fluorohydrocarbon group, a cyano group, a nitro group, a hydroxyl group, a mercapto group, or a silyl group.

3. The photopolymerizable composition of claim 1, wherein the tribromoacetic acid ester has a molecular weight of from 500 to 1000, and is represented by formula (B1), 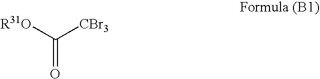
wherein R₃₁ represents an aryl group, a cycloalkyl group or an alkenyl group.

4. The photopolymerizable composition of claim 1, wherein the iron arene compound is a compound having the following formula (1), (2) or (3), 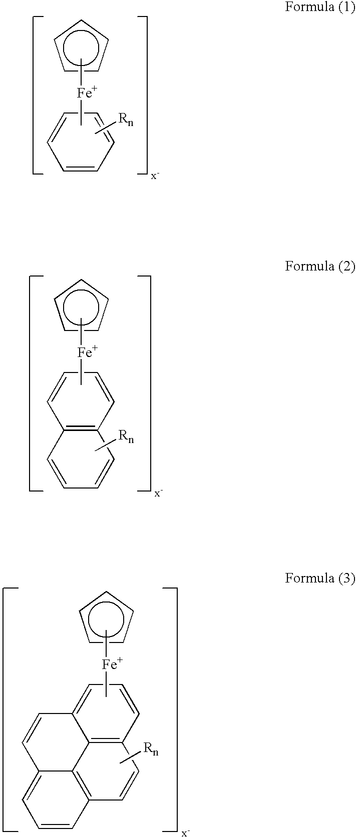
wherein R represents an alkyl group; n represents an integer of from 1 to 4; and X⁻ represents an anionic group, provided that when n is 2 or more, plural R's may be the same or different, and the adjacent two R's may combine with each

5. The photopolymerizable composition of claim 1, wherein the photopolymerizable composition further contains a polymeric compound.

6. The photopolymerizable composition of claim 5, wherein the polymeric compound has an acid value of from 10 to 150.

7. The photopolymerizable composition of claim 5, wherein the polymeric compound is a polymer having an acryloyl group or a methacryloyl group in the side chain.

8. The photopolymerizable composition of claim 1, wherein the photopolymerizable composition contains the ethylenically unsaturated monomer in an amount of from 20 to 70% by weight of total solid content of the composition, the photopolymerization initiator in an amount of from 0.1 to 20% by weight of the monomer content, and the sensitizing dye in an amount of from 0.05 to 30% by weight of the monomer content.

9. A light sensitive planographic printing plate material comprising a support, and provided thereon, a photopolymerizable light sensitive layer containing the photopolymerizable composition of claim 1, wherein the photopolymerizable light sensitive layer further contains a polymeric binder, which is a polymer having an acryloyl group or a methacryloyl group in the polymer side chain.

10. A process of manufacturing a planographic printing plate comprising the step of:
imagewise scanning-exposing the light sensitive planographic printing plate material of claim 9 to laser beams with a wavelength of from 350 to 450 nm.
